(19) United States
(12) Patent Application Publication
(10) Pub. No.: US 2022/0208732 A1
(43) Pub. Date: Jun. 30, 2022

(54) MULTI-DIE CO-PACKED MODULE AND MULTI-DIE CO-PACKING METHOD

(71) Applicant: Chengdu Monolithic Power Systems Co., Ltd., Chengdu (CN)

(72) Inventors: Yingjiang Pu, Chengdu (CN); Hunt Jiang, Saratoga, CA (US)

(21) Appl. No.: 17/545,282

(22) Filed: Dec. 8, 2021

(30) Foreign Application Priority Data
Dec. 30, 2020 (CN) 202011611062.8

(51) Int. Cl. H01L 25/065; H01L 23/48; H01L 23/00

(52) U.S. Cl. CPC H01L 25/0657; H01L 23/481; H01L 24/16; H01L 2224/16148; H01L 2225/06517; H01L 2225/06541; H01L 2924/15311; H01L 2225/06513

(57) ABSTRACT

A multi-die co-packed module with an embedded die embedded in a substrate, an electrical component mounted above the substrate, and a flip chip die placed between the substrate and the electrical component or below the substrate. The package is compact and low cost.

### CROSS-REFERENCE TO RELATED APPLICATIONS

This application claims priority to and the benefit of Chinese Patent Application No. 202011611062.8, filed Dec. 30, 2021, which is incorporated herein by reference in its entirety.

### FIELD

The present invention relates to semiconductor packages, and more particularly relates to multi-die co-packed modules.

### BACKGROUND

The requirements for customer electronics products have increased significantly in recent years. Miniaturization and portability are overwhelming trends which push the IC package to be more compact. Accordingly, the electronic portable devices become smaller and smaller along with more functions and better performances. Thus, today's power supply systems are required to have smaller size along with higher power output, more functions and better efficiency. Under these requirements, some technology incorporate switching devices such as FETs and controllers into a monolithic die. However, the controllers typically adopt CMOS process which may need 18-20 masks during fabrication, while the FETs typically adopt DMOS process which needs 8-9 masks during the fabrication. So such monolithic die costs a lot in order to fabricate the FETs together with the controller.

### SUMMARY

It is an object of the present invention to provide a solution, which solves the above problems.

In accomplishing the above and other objects, there has been provided, in accordance with an embodiment of the present invention, a multi-die co-packed module, comprising: an embedded die, configured to be embedded in a substrate; an electrical component, configured to be mounted above the substrate, the electrical component die being electrically coupled to the substrate by way of a first conductor; and a flip chip die, configured to be a) mounted between the substrate and the electrical component or b) placed below the substrate, the flip chip being configured to contact with the substrate by way of a second conductor.

In accomplishing the above and other objects, there has been provided, in accordance with an embodiment of the present invention, a multi-die co-packed chip, comprising: an input pin, configured to receive an input voltage, the input pin electrically coupled to a first die on which a high side power switch is fabricated; an output pin, electrically coupled to an electrical component, the electrical component being placed above a substrate; a ground pin, electrically coupled to a second die on which a low side power switch is fabricated; and a control pin, configured to receive a control signal, the control pin electrically coupled to a third die on which a control circuit is fabricated; wherein either one of the first die, the second die or the third die is embedded in the substrate as an embedded die; and the remaining two dies: a) are both mounted between the substrate and the electrical components as flip chip dies, or b) are both placed below the substrate as flip chip dies; or c) are respectively placed below the substrate, and placed between the substrate and the electrical components as flip chip dies.

In accomplishing the above and other objects, there has been provided, in accordance with an embodiment of the present invention, a multi-die co-packing method, comprising: embedding an embedded die in a substrate, the substrate having multiple metal layers; placing an electrical component above the substrate; mounting a flip chip die a) between the substrate and the electrical component or b) below the substrate; electrically coupling the embedded die, the flip chip die, the electrical component and the substrate by way of a conductor; and molding the embedded die, the flip chip die, the electrical component, and the substrate as a package.

### BRIEF DESCRIPTION OF THE DRAWINGS

FIG. 1 schematically shows a sectional view of a multi-die co-packed module 100 in accordance with an embodiment of the present invention.

FIG. 2 schematically shows a sectional view of a multi-die co-packed module 200 in accordance with an embodiment of the present invention.

FIG. 3 schematically shows a sectional view of a multi-die co-packed module 300 in accordance with an embodiment of the present invention.

FIG. 4 schematically shows a sectional view of a multi-die co-packed module 400 in accordance with an embodiment of the present invention.

FIG. 5 schematically shows a sectional view of a multi-die co-packed module 500 in accordance with an embodiment of the present invention.

FIG. 6 schematically shows a sectional view of a multi-die co-packed module 600 in accordance with an embodiment of the present invention.

FIG. 7 schematically shows a sectional view of a multi-die co-packed module 700 in accordance with an embodiment of the present invention.

FIG. 8 schematically shows a sectional view of a multi-die co-packed module 800 in accordance with an embodiment of the present invention.

FIG. 9 schematically shows a sectional view of a multi-die co-packed module 900 in accordance with an embodiment of the present invention.

FIG. 10 schematically shows a circuit configuration of a multi-die co-packed module 1000 in accordance with an embodiment of the present invention.

FIG. 11 schematically shows a flowchart 1100 of a multi-die co-packing method in accordance with an embodiment of the present invention.

The use of the similar reference label in different drawings indicates the same of like components.

### DETAILED DESCRIPTION

Embodiments of circuits for multi-die co-packed module incorporating embedded die and flip chip dies are described in detail herein. In the following description, some specific details, such as example circuits for these circuit components, are included to provide a thorough understanding of embodiments of the invention. One skilled in relevant art will recognize, however, that the invention can be practiced without one or more specific details, or with other methods, components, materials, etc.

The following embodiments and aspects are illustrated in conjunction with circuits and methods that are meant to be exemplary and illustrative. In various embodiments, the above problem has been reduced or eliminated, while other embodiments are directed to other improvements.

FIG. 1 schematically shows a sectional view of a multi-die co-packed module 100 in accordance with an embodiment of the present invention. In the example of FIG. 1, the multi-die co-packed module 100 comprises: an embedded die 101, configured to be embedded in a substrate 110; a flip chip die 102, configured to be mounted above the substrate 110, the flip chip die 102 being configured to contact with the substrate 110 by way of a first conductor 111 (e.g., a contact bump, or a via structure, or a metal trace); and an electrical component (e.g., an inductor, a capacitor, etc.) 130, configured to be placed above the flip chip die 102, the electrical component 130 being configured to contact with the substrate 110 by way of the first conductor 111.

In one embodiment of the present invention, integrated circuit/circuits and electric contact pads (e.g. contact bumps) are formed on an active surface (first surface) 11T of the embedded die 101. In one embodiment of the present invention, this active surface is also called as an upper surface or as a top surface; and the embedded die 101 also has a second surface opposite to the first surface, which is also called as a bottom surface.

One skilled in the art should realize that the term “flip chip die” in one embodiment may include any die that the contact area of the die directly connects with lead frame structure or package substrate by bumps; the term “substrate” may refer to a package-level material similar as that used in a printed circuit board (PCB), which typically has multiple metal layers; and the term “contact bump” may refer to a small metal solid in a ball or pillar shape usually comprises the solder material used to directly connect two contact areas.

In one embodiment of the present invention, vias are added in the dies and in the substrate, which are then filled with metal material such as copper, to form metal traces between different dies, between the dies and the substrate, and between the dies and the external contact.

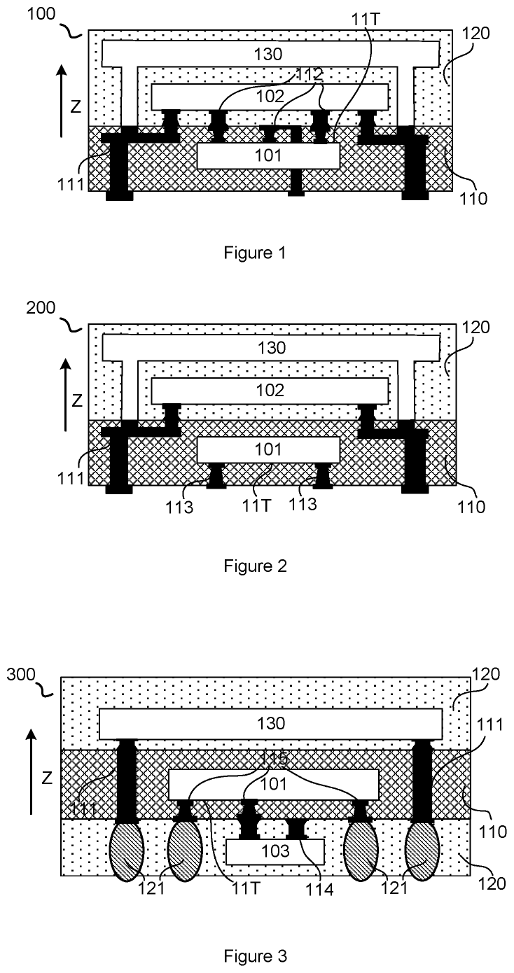

In one embodiment of the present invention, the active surface 11T of the embedded die 101 may face up (i.e., the active surface 11T faces to the flip chip die 102, as shown in FIG. 1), or face down (the active surface 11T is back to the flip chip die 102, as shown in FIG. 2). As shown in FIG. 1, when the active surface 11T of the embedded die 101 faces up, the active surface 11T of the embedded die 101 is configured to contact with the flip chip die 102 and the substrate 110 by way of a second conductor 112. As shown in FIG. 2, when the active surface 11T of the embedded die 101 faces down, the active surface 11T of the embedded die 101 is configured to contact with the substrate 110 by way of a third conductor 113.

In one embodiment of the present invention, the second conductor 112 is led out from a bottom surface of the substrate 110 by way of metal traces and through vias, so as to act as an input and/or an output terminal of the embedded die 101.

In the embodiments of FIG. 1 and FIG. 2, the flip chip die 102 is placed above the substrate 110 and below the electrical component 130. However, one skilled in the art should realize that in other embodiments of the present invention, the flip chip die 102 may be placed at any other appropriate positions, as shown in FIG. 3.

FIG. 3 schematically shows a sectional view of a multi-die co-packed module 300 in accordance with an embodiment of the present invention. In the example of FIG. 3, the multi-die co-packed module 300 comprises: an embedded die 101, configured to be embedded in a substrate 110; a flip chip die 103, configured to be placed below the substrate 110 (e.g., be attached to the bottom surface of the substrate 110); and an electrical component (e.g., an inductor, a capacitor, etc.) 130, configured to be placed above the substrate 110, the electrical component 130 being configured to contact with the substrate 110 by way of a first conductor 111.

In the example of FIG. 3, the active surface 11T of the embedded die 101 faces down, so as to have the active surface 11T contact with the flip chip die 103 and the substrate 110 by way of a conductor 115.

In one embodiment of the present invention, the multi-die co-packed modules 100, 200 and 300 further comprise: molding material 120, encapsulating and protecting the flip chip die 102 and/or 103, the electrical component 130, and the substrate 110. In one embodiment of the present invention, molding material comprises a kind of electrical insulation material such as epoxy.

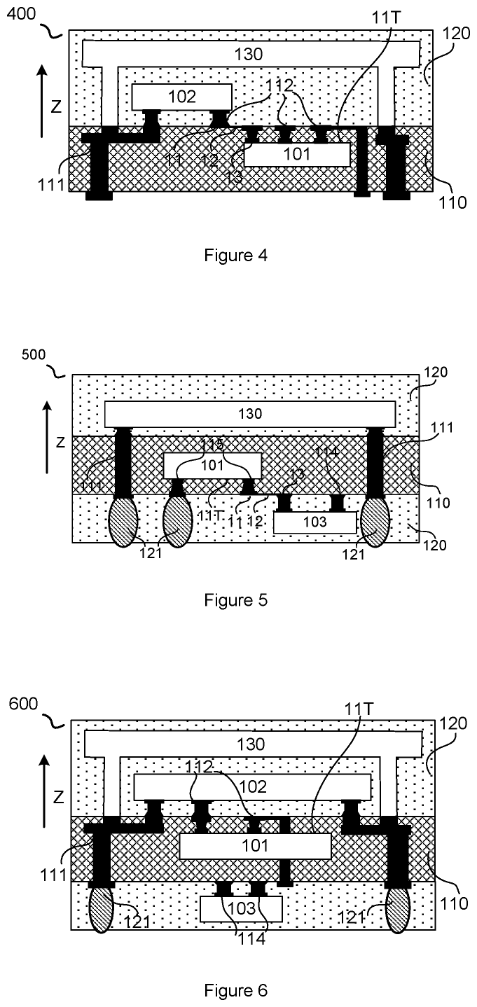

In the above embodiments shown in FIGS. 1, 2 & 3, partial periphery of the embedded die 101 is overlapped with partial periphery of the flip chip die 102 (and/or 103) in vertical direction (Z direction as shown in FIGS. 1, 2 & 3), i.e., the embedded die 101 has an active surface, the active surface being at least partly overlapped by the flip chip die 102, so that the conductor between the flip chip die 102 (and/or 103) and the embedded die 101 has shortest vertical contact bump and less parasitic resistance. In one embodiment of the present invention, the vertical direction is a direction vertical to the die plane, i.e., vertical to the active surface of the embedded die 101. However, one skilled in the art should realize that in other embodiments of the present invention, the embedded die 101 may have no overlap with the flip chip die 102 (and/or 103) in vertical direction, as shown in FIG. 4 and FIG. 5.

FIG. 4 schematically shows a multi-die co-packed module 400 in accordance with an embodiment of the present invention. The multi-die co-packed module 400 in FIG. 4 is similar to the multi-die co-packed module 100 in FIG. 1, with a difference that in the embodiment of FIG. 4, the embedded die 101 has no overlap with the flip chip die 102 in vertical direction; and the second conductor 112 between the embedded die 101 and the flip chip die 102 comprises a contact bump 11 (the part that contacts with the flip chip die 102 in vertical direction), a metal trace 12 (in planar direction) and a via structure 13 (the part that contacts with the embedded die 101 in vertical direction).

FIG. 5 schematically shows a multi-die co-packed module 500 in accordance with an embodiment of the present invention. The multi-die co-packed module 500 in FIG. 5 is similar to the multi-die co-packed module 300 in FIG. 3, with a difference that in the embodiment of FIG. 5, the embedded die 101 has no overlap with the flip chip die 103 in vertical direction; and the conductor 115 between the embedded die 101 and the flip chip die 103 comprises a via structure (or a contact bump) 11 (the part that contacts with the embedded die 101 in vertical direction), a metal trace 12 (in planar direction), and a contact bump 13 (the part that contacts with the flip chip die 103 in vertical direction).

That is, in some of the embodiments of the present invention, the conductor may comprise a contact bump and a via structure (e.g., the conductor between the embedded die 101 and the flip chip die 102 (and/or 103) as shown in FIG. 1 and FIG. 3); in some of the embodiments of the present invention, the conductor may comprise a contact bump, a via structure and a metal trace (e.g., the conductor between the embedded die 101 and the flip chip die 102 as shown in FIG. 4); and in some of the embodiments of the present invention, the conductor may comprise a contact bump and a through via, and/or a metal trace (e.g., the conductor between the flip chip die 102 and the substrate 110 in FIGS. 1, 2 & 4).

FIG. 6 schematically shows a sectional view of a multi-die co-packed module 600 in accordance with an embodiment of the present invention. In the example of FIG. 6, the multi-die co-packed module 600 comprises: an embedded die 101, configured to be embedded in a substrate 110; a high flip chip die 102, configured to be mounted above the substrate 110, the flip chip die 102 being electrically contact with the substrate 110 by way of a first conductor 111; a low flip chip die 103, configured to be placed below the substrate 110 (e.g., be attached to a bottom surface of the substrate 110), the low flip chip die 103 being electrically contact with the substrate 110 by way of a conductor 114; and an electrical component (e.g., an inductor, a capacitor, etc.) 130, configured to be placed above the flip chip die 102, the electrical component 130 being contact with the substrate 110 by way of the first conductor 111.

In the example of FIG. 6, the active surface 11T of the embedded die 101 faces up, so as to have the active surface 11T contact with the high flip chip die 102 by way of a second conductor 112. However, one skilled in the art should realize that in other embodiments of the present invention, the active surface 11T may face down, so as to have the active surface 11T contact with the low flip chip die 103 by way of the conductor 114 (as shown in FIG. 3).

Thus, in one embodiment of the present invention, the multi-die co-packed module comprises: an embedded die 101, configured to be embedded in a substrate 110; an electrical component (e.g., an inductor, a capacitor, etc.) 130, configured to be placed above the substrate 110, the electrical component 130 being contact with the substrate 110 by way of a first conductor 111; and a flip chip die (102 and/or 103), configured to be mounted above the substrate 110 and below the electrical component 130, or configured to be placed below the substrate 110, the flip chip die (102 and/or 103) being electrically contact with the substrate 110 by way of a second conductor.

In one embodiment of the present invention, the term “high flip chip die” may refer to a flip chip die having an active surface facing down; and the term “low flip chip die” may refer to a flip chip die having an active surface facing up.

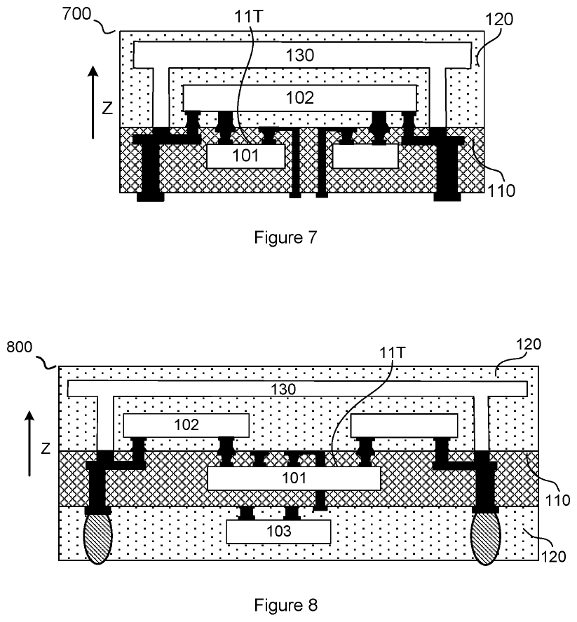

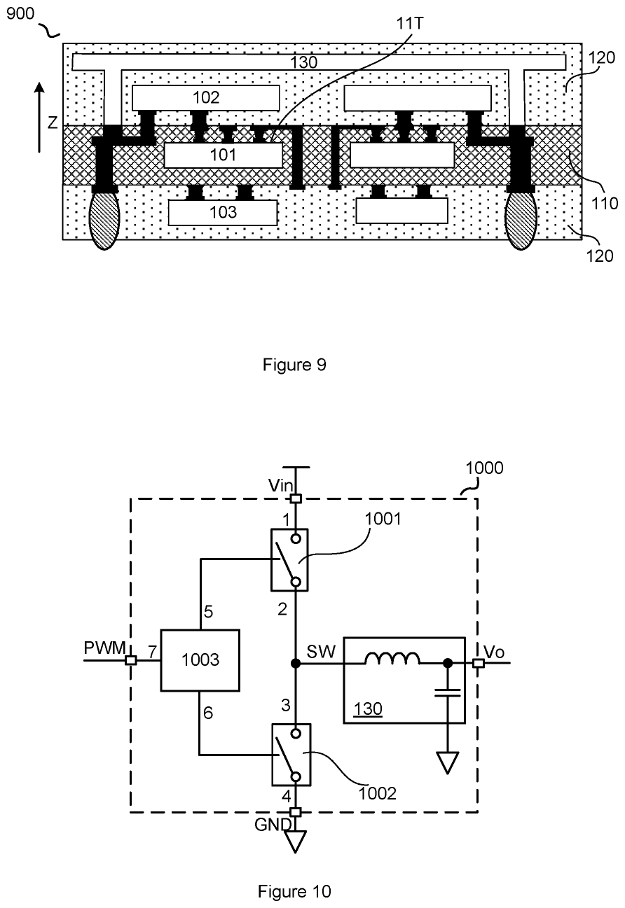

Several embodiments of the foregoing multi-die co-packed modules have one embedded die with one flip chip die and one electrical component co-packed in one package outline. However, one skilled in the art should realize that in other embodiments of the present invention, the multi-die co-packed module may comprise one or more embedded dies and one or more flip chip dies co-packed with electrical components. As schematically shown in FIGS. 7-9, sectional views of multi-die co-packed modules 700, 800, and 900 are illustrated. These embodiments schematically show the combination of one or two embedded dies and one or two flip chip dies co-packed with electrical components. However, one skilled in the art should realize that in other embodiments of the present invention, the multi-die co-packed module may comprise any desired number of embedded dies, flip chip dies, and electrical components co-packed in one package outline; and the embedded die may have overlap or have no overlap with the flip chip die in vertical direction.

In one embodiment of the present invention, the embedded die 101 and the flip chip die (the high flip chip die 102 and/or the low flip chip die 103) may respectively comprise a switch power device and a controller operable to control the switch power devices. For example, the embedded die 101 may comprise a switch power device, and the flip chip die may comprise the corresponding controller; or the flip chip die may comprise a switch power device, and the embedded die 101 may comprise the corresponding controller. One skilled in the art should realize that in other embodiments of the present invention, the embedded die and the flip chip die may comprise any other desired circuits and devices.

FIG. 10 schematically shows a multi-die co-packed module 1000 in accordance with an embodiment of the present invention. The module 1000 comprises a buck converter. Specifically, the multi-die co-packed module 1000 comprises: an input pin Vin, configured to receive an input voltage, the input pin Vin electrically coupled to a first die 1001 on which a high side power switch is fabricated; an output pin Vo, electrically coupled to an electrical component 130, the electrical component being placed above a substrate; a ground pin GND, electrically coupled to a second die 1002 on which a low side power switch is fabricated; and a control pin PWM, configured to receive a control signal (e.g. from a pre-stage), the control pin PWM electrically coupled to a third die 1003 on which a control circuit is fabricated; wherein either one of the first die 1001, the second die 1002 or the third die 1003 is embedded in the substrate as an embedded die, and the remaining two dies a) are both mounted between the substrate and the electrical components (i.e. above the substrate and below the electrical components) as flip chip dies, or b) are both placed below the substrate as flip chip dies; or c) are respectively placed below the substrate, and placed between the substrate and the electrical components as flip chip dies.

Continue referring to FIG. 10, the first die 1001 having a first terminal 1 electrically coupled to the input pin Vin, a second terminal 2 electrically coupled to a switch node SW, and a control terminal electrically coupled to the third die 1003. The second die 1002 having a first terminal 3 electrically coupled to the switch node SW, a second terminal 4 electrically coupled to the ground pin GND, and a control terminal electrically coupled to the third die 1003. The third die 1003 having an input terminal 7 electrically coupled to the control pin PWM, a first output terminal 5 electrically coupled to the control terminal of the first die 1001, and a second output terminal 6 electrically coupled to the control terminal of the second die 1002.

Several embodiments of the foregoing multi-die co-packed module provide much compact solution for smaller package size and less parasitic RLC (resistance, inductance and capacitance), which brings better performance. Unlike the conventional technique, several embodiments of the foregoing multi-die co-packed module may adopt different process to fabricate different dies (e.g., the flip chip die with one process and the embedded die with another process), and then co-pack the dies together with electrical components. Some of the dies are embedded in the substrate, and the other dies are mounted between the electrical components and the substrate or placed below the substrate. The flip chip dies may be configured to contact with the substrate through contact bumps. Thus the total cost is down. In addition, the embedded die may be overlapped by the flip chip die, resulting a smaller package size, which further saves the cost.

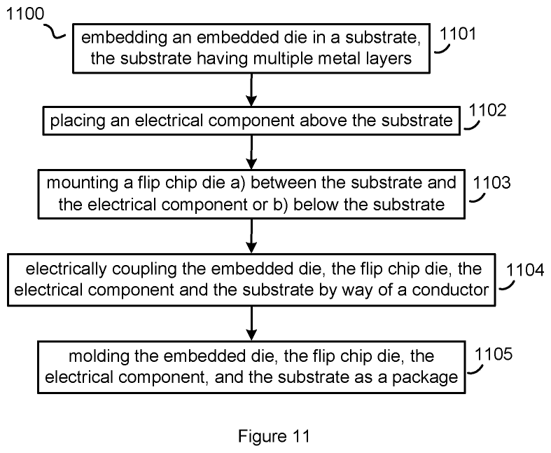

FIG. 11 schematically shows a flowchart 1100 of a multi-die co-packing method in accordance with an embodiment of the present invention. The method comprising:

Step 1101, embedding an embedded die in a substrate, the substrate having multiple metal layers.

Step 1102, placing an electrical component above the substrate.

Step 1103, mounting a flip chip die a) between the substrate and the electrical component or b) below the substrate.

Step 1104, electrically coupling the embedded die, the flip chip die, the electrical component and the substrate by way of a conductor. And

Step 1105, molding the embedded die, the flip chip die, the electrical component, and the substrate as a package.

In one embodiment of the present invention, the method further comprising pre-planting solder balls at the bottom surface of the substrate.

In one embodiment of the present invention, the conductor between the embedded die, the flip chip die and the substrate may comprise a contact bump, a via structure and/or a metal trace. In another embodiment of the present invention, the conductor between the embedded die, the flip chip die and the substrate may comprise a contact bump, and a through via.

In one embodiment of the present invention, the embedded die and the flip chip die is respectively led out through different metal layers of the substrate, to act as external pins.

In one embodiment of the present invention, partial periphery of the embedded die is overlapped by the flip chip die in vertical direction perpendicular with the embedded die.

It is to be understood in these letters patent that the meaning of “A” is coupled to “B” is that either A and B are connected to each other as described below, or that, although A and B may not be connected to each other as described above, there is nevertheless a device or circuit that is connected to both A and B. This device or circuit may include active or passive circuit elements, where the passive circuit elements may be distributed or lumped-parameter in nature. For example, A may be connected to a circuit element that in turn is connected to B.

This written description uses examples to disclose the invention, including the best mode, and also to enable a person skilled in the art to make and use the invention. The patentable scope of the invention may include other examples that occur to those skilled in the art.

What is claimed is:

1. A multi-die co-packed module, comprising:
an embedded die, configured to be embedded in a substrate;
an electrical component, configured to be mounted above the substrate, the electrical component die being electrically coupled to the substrate by way of a first conductor; and
a flip chip die, configured to be a) mounted between the substrate and the electrical component or b) placed below the substrate, the flip chip being configured to contact with the substrate by way of a second conductor.

2. The multi-die co-packed module of claim 1, wherein:
the substrate comprises multiple layers, and
the embedded die and the flip chip die is respectively led out through different metal layers of the substrate, to act as external pins.

3. The multi-die co-packed module of claim 1, wherein the embedded die has an active surface, the active surface die being at least partly overlapped by the flip chip die.

4. The multi-die co-packed module of claim 1, wherein:
if the flip chip die is mounted between the substrate and the electrical component, the flip chip die is a high flip chip die; and wherein
the multi-die co-packed module further comprises a low flip chip die, placed below the substrate.

5. The multi-die co-packed module of claim 1, wherein:
if the flip chip die is placed below the substrate, the flip chip die is a low flip chip die; and wherein:
the multi-die co-packed module further comprises a high flip chip die, mounted between the substrate and the electrical component.

6. A multi-die co-packed module, comprising:
an input pin, configured to receive an input voltage, the input pin electrically coupled to a first die on which a high side power switch is fabricated;
an output pin, electrically coupled to an electrical component, the electrical component being placed above a substrate;
a ground pin, electrically coupled to a second die on which a low side power switch is fabricated; and
a control pin, configured to receive a control signal, the control pin electrically coupled to a third die on which a control circuit is fabricated; wherein
either one of the first die, the second die or the third die is embedded in the substrate as an embedded die; and
the remaining two dies: a) are both mounted between the substrate and the electrical components as flip chip dies, or b) are both placed below the substrate as flip chip dies; or c) are respectively placed below the substrate, and placed between the substrate and the electrical components as flip chip dies.

7. The multi-die co-packed chip of claim 6, wherein:
the embedded die has an active surface, the active surface being at least partly overlapped by the flip chip dies.

8. The multi-die co-packed chip of claim 6, wherein:
the flip chip dies are electrically coupled to the substrate and the embedded die by way of a conductor.

9. A multi-die co-packing method, comprising:
embedding an embedded die in a substrate, the substrate having multiple metal layers;
placing an electrical component above the substrate;
mounting a flip chip die a) between the substrate and the electrical component or b) below the substrate;
electrically coupling the embedded die, the flip chip die, the electrical component and the substrate by way of a conductor; and
molding the embedded die, the flip chip die, the electrical component, and the substrate as a package.

10. The multi-die co-packing method of claim 9, wherein:
the embedded die has an active surface, the active surface being at least partly overlapped by the flip chip die.

11. The multi-die co-packing method of claim 9, wherein:
the conductor comprises a contact bump, a via structure and/or a metal trace.

12. The multi-die co-packing method of claim 9, wherein:
the conductor comprises contact bump and a through via.

13. The multi-die co-packing method of claim 9, wherein:
the embedded die, and the flip chip die, is respectively led out through different metal layers of the substrate, to act as external pins.
